(19) United States
(12) Patent Application Publication
(10) Pub. No.: US 2004/0080012 A1
(43) Pub. Date: Apr. 29, 2004

(54) Nonvolatile memory device having asymmetric source/drain region and fabricating method thereof

(76) Inventor: Sung-Ho Kim, Kyungki-do (KR)

Correspondence Address: MARGER JOHNSON & McCOLLOM, P.C., 1030 S.W. Morrison Street, Portland, OR, 97205, US

(21) Appl. No.: 10/682,128

(22) Filed: Oct. 7, 2003

(30) Foreign Application Priority Data
Oct. 28, 2002 (KR) 2002-65782

(51) Int. Cl. H01L 23/58

(52) U.S. Cl. 257/492

(57) ABSTRACT

The present invention relates to a nonvolatile memory device having asymmetric source/drain regions and a fabricating method thereof. In the device, a first and second impurity regions are formed in a substrate, and are separated by a first channel region and a second channel region. A tunnel insulating layer, a charge storing layer, and a gate interlayer insulating layer is disposed on the substrate in the first channel region, with the gate interlayer insulating layer being extended over the substrate in the second channel region. A control gate is then disposed over the previously formed layers in both regions. The first channel region and the first impurity region are, respectively, wider than the second channel region and the second impurity region. Thus, the erase speed of the device can be increased in an erase operation, by allowing an increased hot-hole injection rate.

### RELATED APPLICATION AND CLAIM TO PRIORITY

This application claims priority form Korean Patent Application No. 2002-65782, filed on Oct. 28, 2002, the contents of which are herein incorporated by reference in their entirety.

### FIELD OF THE INVENTION

The present invention generally relates to a semiconductor memory device and a method for fabricating the same. More specifically, the present invention is directed to a nonvolatile memory device having asymmetric source/drain region and to a fabrication method of this device.

### BACKGROUND OF THE INVENTION

Nonvolatile memory devices, such as Ferro-electric Random Access Memory (FRAM), Erasable and Programmable Read Only Memory (EPROM), and Electrically Erasable and Programmable Read Only Memory (EEPROM), have lately attracted considerable attention. Data stored in EPROMs and EEPROMs can be altered by changing the amount of electric charge stored in the floating gate of the memory cells, because a threshold voltage of a channel is dependent on the electric charge of the floating gate. An erase operation of EEPROM can be accomplished on the entire memory cell array or on a portion of the blocks that constitute a memory cell array. An EEPROM corresponding to the latter case is called a FLASH memory device.

The FLASH memory may be further divided into floating gate-types and floating trap-types of devices. One known type of FLASH memory is a silicon-oxide-nitride-oxide-silicon (SONOS) device.

The SONOS-type memory utilizes a mechanism of storing electric charges in trap sites of a silicon nitride layer, in order to store data. In general a floating gate-type FLASH memory is restricted on how small a unit-cell size can be, and further has the problem of needing a high operation voltage to perform the program and erase operations. The SONOS device, on the other hand, allows a decrease in power-consumption and operation voltage, and an increase in chip integration.

FIGS. 1 and 2 are a top plan view and a cross-sectional view, respectively, of a split gate-type SONOS device according to prior art.

Referring to FIGS. 1 and 2, a field region 4 is formed in substrate 2 to define an active region 3. Source region 16s and drain region 16d are formed in the active region 3 and are separated by a first and second channel region L1 and L2. A tunnel insulating layer 6 and a charge storing layer 8 are formed on the first channel region L1. A control gate 12 is formed to cross over the first channel region L1 and the second channel region L2. A gate interlayer insulating layer 10 is interposed between the control gate 12 and the charge storing layer 8 in region L1, and between the control gate 12 and the substrate in the second channel region L2. A drain contact hole 20d and a source contact hole 20s are formed on the drain region 16d and the source region 16s, respectively.

Channel-hot electron injection (CHEI) or Fowler-Nordheim tunneling (FN tunneling) is utilized for the program operation of the split gate-type SONOS device, in which electrons are trapped in the charge storing layer 8 through the tunnel insulating layer 6. The CHEI process of injecting electrons into the charge storing layer 8 is shown by an arrow 30 of FIG. 2. The threshold voltage of SONOS device is varied by an amount of the trapped electrons, thus datum stored in a specific cell of SONOS device is defined by either an on-state or an off-state.

A hot-hole injection is utilized for the erase operation, in which the trapped electrons are detrapped. The hot-hole injection process of detrapping the trapped electrons from the charge storing layer 8 is shown by an arrow 40 of FIG. 2.

However, in general with the split gate-type SONOS device in prior art, the amount of hot holes injected into the charge storing layer 8 during the erase operation is too small to obtain a very fast erase speed.

### SUMMARY OF THE INVENTION

It is a feature of the present invention to provide a split gate type SONOS device having a fast erase speed by utilizing a structure that effectively increase the hot-hole injection rate during the erase operation.

It is another feature of the present invention to provide a method of fabricating a split gate type SONOS device having a fast erase speed.

According to one aspect of the present invention, a split gate-type SONOS device is formed which has an active region with a comparatively large area in order to increase the erase operation speed. One embodiment comprises a split gate-type SONOS device with a first and second impurity regions that are formed in a substrate, and are separated by a first channel region and a second channel region. A tunnel insulating layer, a charge storing layer, and a gate interlayer insulating layer are disposed on the substrate in the first channel region, with the gate interlayer insulating layer being extended over the substrate in the second channel region. A control gate is then disposed over the previously formed layers in both regions. The first channel region and the first impurity region are, respectively, wider than the second channel region and the second impurity region. Thus, the erase speed of the device can be increased in an erase operation, by allowing an increased hot-hole injection rate.

According to another aspect of the present invention, an improved method of fabricating a split gate-type SONOS device is provided. The method includes forming a field region, which defines both a wide and a narrow active region in a substrate, where the narrow active region has a narrower width than the wide active region. A tunnel insulating layer and a charge storing layer pattern are formed on a predetermined region of the wide active region. A control gate is formed to cross over the charge storing layer pattern and a predetermined region of the narrow active region. A gate interlayer insulating layer may be disposed between the control gate and the charge storing layer pattern, and additionally be disposed between the control gate and the narrow active region. A first impurity region and a second impurity region are formed by injecting impurities into the active regions at both sides of the control gate.

### BRIEF DESCRIPTION OF THE DRAWINGS

FIGS. 1 and 2 are a top plan view and a cross-sectional view, respectively, illustrating the split gate-type SONOS device according to the prior art.

FIGS. 3 and 4 are a top plan view and a cross-sectional view, respectively, illustrating a split gate-type SONOS device according to an embodiment of the present invention.

FIGS. 5 to 7 are cross-sectional views illustrating a method of fabricating a split gate-type SONOS device according to an embodiment of the present invention.

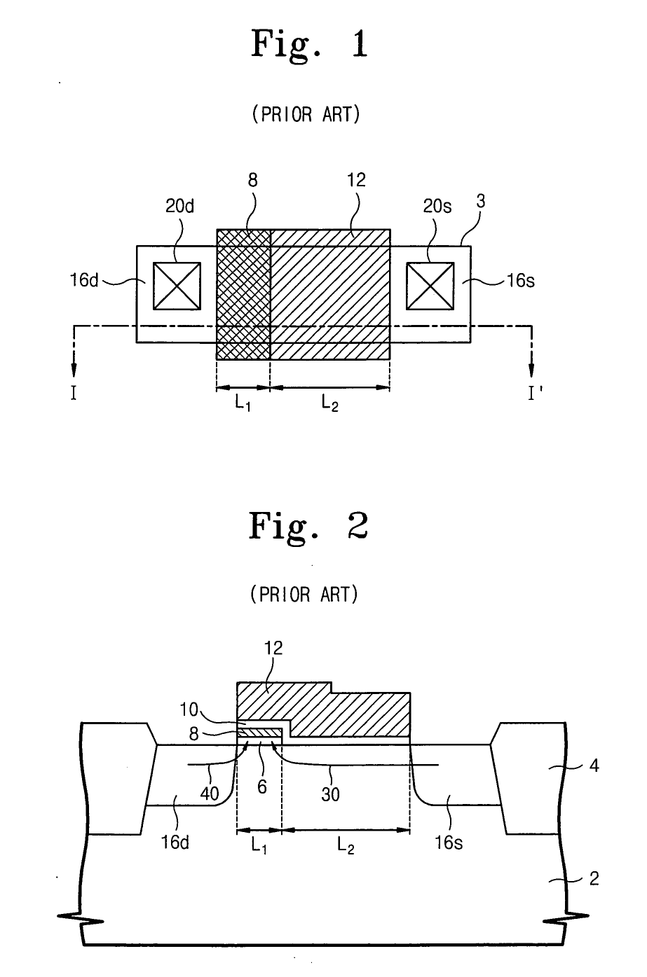

### DETAILED DESCRIPTION OF THE PRESENT INVENTION

The present invention will now be described more fully hereinafter with reference to the accompanying drawings, in which embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

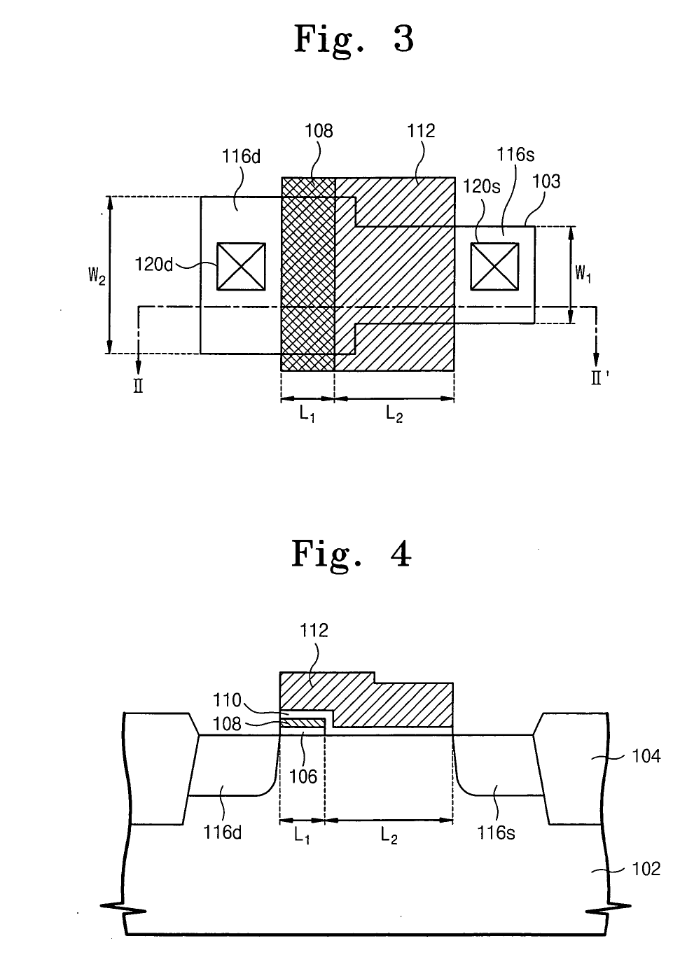

FIGS. 3 and 4 are a top plan view and a cross-sectional view illustrating the split gate-type SONOS device according to an embodiment of the present invention. FIG. 4 illustrates a cross-sectional view shown along the line II-II′ of FIG. 3.

Referring to FIGS. 3 and 4, a field region 104 is formed in substrate 102 to define an active region 103. Source region 116s and drain region 116d are formed in the active region 103 and separated by a first channel region L1 and a second channel region L2. A tunnel insulating layer 106 and a charge storing layer 108 are formed on the first channel region L1. A control gate 112 is formed to cross over the first channel region L1 and the second channel region L2. A gate interlayer insulating layer 110 is interposed between the control gate 112 and the charge storing layer 108 in region L1, and between the control gate 112 and the substrate 102 in the second channel region L2. A drain contact hole 120d and a source contact hole 120s may be formed on the drain region 116d and the source region 116s, respectively.

Referring to FIG. 3, the width W2 of the drain region 116d and first channel region L1 is relatively wider than the width W1 of the source region 116s and second channel region L2. Therefore, the split gate-type SONOS device can increase its effective hot-hole injection rate resulting in a faster erase speed according to the present invention.

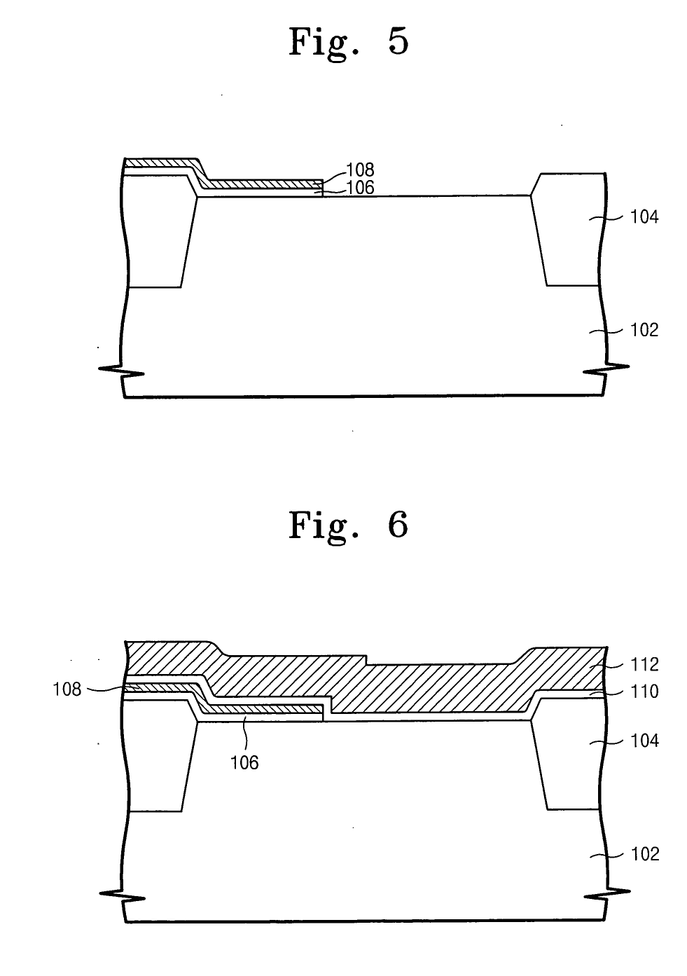

FIGS. 5 to 7 are cross-sectional views illustrating a method of fabricating the split gate-type SONOS device according to an embodiment of the present invention.

Referring to FIG. 5, a field region 104 is formed in a substrate 102 to define an active region. In the top plan view, the active region is formed into an asymmetric shape. That is, the active region is divided into a wide active region and a narrow active region. The narrow active region has a narrow width than the wide active region. A predetermined drain region of SONOS device and a predetermined first channel region will be formed in the wide active region, and a predetermined source region of SONOS device and a predetermined second channel region will be formed in the narrow active region, in subsequent processes.

A tunnel insulating layer 106 and a charge storing layer 108 are sequentially formed on the substrate having the active region. Then, the tunnel insulating layer 106 and the charge storing layer 108 are patterned to remain only on the wide active region by removing the parts on the narrow active region. The tunnel insulating layer 106 may be formed of silicon oxide, and the charge storing layer 108 may be formed of silicon nitride.

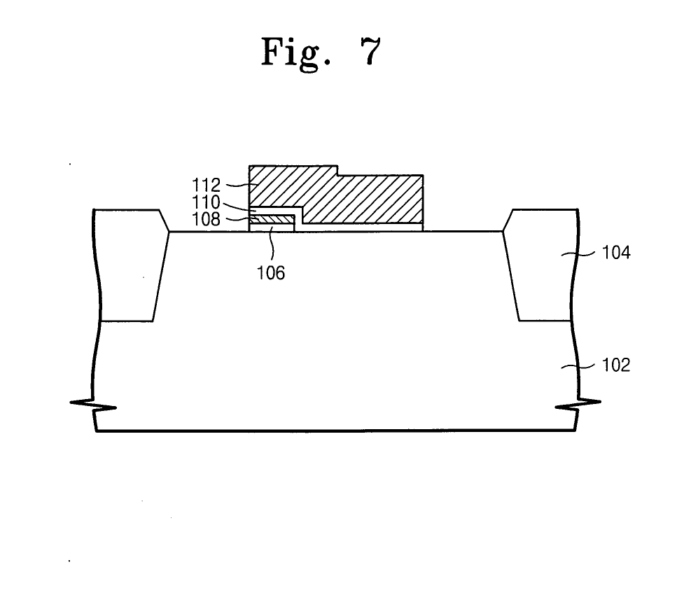

Referring to FIG. 6, a gate interlayer insulating layer 110 and a control gate layer 112 are sequentially stacked on the surface of the substrate having the patterned tunnel insulating layer 106 and charge storing layer 108 on the wide active region and nothing on the narrow active region. The gate interlayer insulating layer 110 may be formed of silicon oxide and the control gate layer 112 may be formed of a doped polycrystalline silicon layer.

Referring to FIG. 7, using conventional photolithographic and etching processes, the control gate layer 112, the gate interlayer insulating layer 110, the charge storing layer 108 and the tunnel insulating layer 106 are patterned to expose the predetermined drain region in the first channel region of the substrate 102. Simultaneously, on the opposite side, the control gate layer 112 and the gate interlayer insulating layer 110 are patterned to expose the predetermined source region in the second channel region of the substrate 102. Therefore, the tunnel insulating layer 106, the charge storing layer 108, and the gate interlayer insulating layer 110 are aligned with the control gate. That is, due to the simultaneous patterning process, the sides of the layers 106, 108, and 110 are automatically aligned with the side of the control gate.

Referring to FIG. 4 again, a drain region 120d and a source region 120s are formed in the predetermined drain region and predetermined source region, respectively, using the field region 104 and the patterned control gate 112 as an ion implantation mask.

According to the present invention, the erase operation speed of SONOS device can be increased by broadening an area of the active region where the hot-hole injection is produced.

While the invention has been shown and described with respect to preferred embodiments thereof, it will be understood by those skilled in the art, that various changes in form and detail may be make without departing from the teaching, sprit and scope of the present invention. The scope of the present invention is limited only by the appended claims.

What is claimed is:

1. A split gate-type SONOS device comprising:
a substrate;
a first impurity region and a second impurity region formed in the substrate, separated by a first channel region and a second channel region;
a control gate crossing over the first channel region and the second channel region; and
a tunnel insulating layer, a charge storing layer, and a gate interlayer insulating layer interposed between the control gate and the substrate in the first channel region, wherein the gate interlayer insulating layer is interposed between the control gate and the substrate in the second channel region, and wherein the first channel region and the first impurity region are wider than the second channel region and the second impurity region, respectively.

2. A split gate-type SONOS device as claimed in claim 1, wherein the first impurity region is a drain region and the second impurity region is a source region.

3. A split gate-type SONOS device as claimed in claim 1, wherein the sides of the tunnel insulating layer, the charge storing layer, and the gate interlayer insulating layer are aligned with the side of the control gate.

4. A split gate-type SONOS device as claimed in claim 1, wherein the control gate is formed of polycrystalline silicon.

5. A split gate-type SONOS device as claimed in claim 1, wherein the charge storing layer is formed of silicon nitride.

6. A split gate-type SONOS device as claimed in claim 1, wherein the tunnel insulating layer is formed of silicon oxide.

7. A split gate-type SONOS device as claimed in claim 1, wherein the gate interlayer insulating layer is formed of silicon oxide.

8. A method of fabricating a split gate-type SONOS device, the method comprising:
forming a field region in a substrate, where the field region defines a wide active region and a narrow active region, wherein the narrow active region has a width narrower than the wide active region;
forming a tunnel insulating layer and a charge storing layer pattern stacked on a section of the wide active region;
forming a control gate crossing over the charge storing layer pattern in the wide active region, and over a section of the narrow active region; and
injecting impurities into the active regions on both sides of the control gate to form a first impurity region and a second impurity region.

9. A method as claimed in claim 8, further comprising forming a gate interlayer insulating layer disposed between the control gate and the charge storing layer pattern in the wide active region, and disposed between the control gate and the substrate in the narrow active region.

10. A method as claimed in claim 8, wherein the control gate is formed of polycrystalline silicon.

11. A method as claimed in claim 8, wherein the charge storing layer is formed of silicon nitride.

12. A method as claimed in claim 8, wherein the tunnel insulating layer is formed of silicon oxide.

13. A method as claimed in claim 9, wherein the gate interlayer insulating layer is formed of silicon oxide.

14. A nonvolatile memory device, comprising:
first and second impurity regions on a substrate separated by a first channel region and a second channel region, said first channel region being wider than said second channel region and said first impurity region being wider than said second impurity region.

15. The device recited in claim 14, further comprising a tunnel insulating layer, a charge storing layer, and a gate interlayer insulating layer disposed on the substrate in said first channel region.

16. The device recited in claim 15, wherein said gate interlayer insulating layer extends over the substrate in the second channel region.

17. The device recited in claim 15, further comprising a control gate disposed over said first and second regions.

18. The device recited in claim 17, wherein said control gate is formed of polycrystalline silicon, said charge storing layer is formed of silicon nitride and said tunnel insulating layer is formed of silicon oxide.

19. The device recited in claim 14, further comprising:
a control gate crossing over said first channel region and said second channel region; and
a tunnel insulating layer, a charge storing layer, and a gate interlayer insulating layer interposed between said control gate and said substrate in the first channel region, wherein the gate interlayer insulating layer is interposed between the control gate and the substrate in the second channel region.

20. A method of fabricating a nonvolatile memory device, the method comprising:
forming a wide active region and a narrow active region on a substrate, forming a charge storing layer pattern on a section of the wide active region;
forming a control gate crossing over the charge storing layer pattern in the wide active region, and over a section of the narrow active region; and
injecting impurities into the active regions on both sides of the control gate to form a first impurity region and a second impurity region.

21. The method recited in claim 20, further comprising forming a field region to define said wide and said narrow active regions.

22. The method recited in claim 20, further comprising forming a tunnel insulating layer on a section of the wide active region.

23. The method recited in claim 20, further comprising forming a gate interlayer insulating layer between said control gate and said charge storing layer pattern.
